(19) United States
(12) Patent Application Publication
(10) Pub. No.: US 2008/0277061 A1
(43) Pub. Date: Nov. 13, 2008

(54) WAFER EDGE CLEANER

(76) Inventors: Hiroyuki Kobayashi, Kodaira (JP); Kenji Maeda, Sagamihara (JP); Masaru Izawa, Hino (JP); Kenetsu Yokogawa, Tsurugashima (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/835,463

(22) Filed: Aug. 8, 2007

(30) Foreign Application Priority Data
May 11, 2007 (JP) 2007-126984

(51) Int. Cl. H01L 21/306; G06F 19/00

(52) U.S. Cl. 156/345.5; 700/95

(57) ABSTRACT

An object of the present invention is to provide a wafer edge cleaner which is capable of removing an undesired material that adheres to an outer periphery of an object to be processed at the low costs and with high throughput. The wafer edge cleaner according to the present invention irradiates a deposited material that has adhered to the rear surface outer periphery of the object to be processed with a laser beam that is at least 30 kW/mm² in the peak power density.

### CLAIM OF PRIORITY

The present invention application claims priority from Japanese application JP2007-126984 filed on May 11, 2007, the content of which is hereby incorporated by reference into this application.

### BACKGROUND OF THE INVENTION

1. Field of the Invention

The present invention relates to wafer edge cleaners, and more particularly to a wafer edge cleaner that is suitable in removing an undesired material that adheres to an outer periphery of a wafer that is to be processed in a semiconductor manufacture.

2. Description of the Related Art

In a process of manufacturing a semiconductor device such as a DRAM or a microprocessor, in order to improve a yield, it is important to reduce the particle contamination. As one of factors that generate the particles, a deposited film is generated on the outer periphery of a rear surface of the wafer which is an object to be processed in a wafer treatment process such as an etching process or a CVD process, and the deposited film is peeled off, for example, during the transportation of the object to be processed into particles. Now, a description will be given of a factor that causes the deposited material to be adhered to the outer periphery of the rear surface of the object to be processed in the etching process with reference to FIGS. 15A and 15B.

In general, a lower electrode 52 for mounting an object (a sample) 2 to be processed which is located within a plasma processing device thereon is designed in such a manner that the object 2 is protruded from the top surface of the electrode, where the object to be processed is put on by about 1 to 2 mm in order to prevent an upper surface of the lower electrode 52 from being wasted by incidence of plasma particles. Ions 94 that have been generated in plasma 93 are entered perpendicularly into the object 2 from the plasma. For that reason, the ions hardly reach a portion that is located behind the plasma 93 such as the outer periphery of the rear surface of the object 2 which is protruded from the surface of the lower electrode on which the object 2 is mounted. On the contrary, neutral particles 95 can be input to the object 2 and a focus ring 53 at diverse angles, and enter the portion that is located behind the plasma while being rebounded from the object 2 or the electrode. Even if the neutral particles 95 adhere to the outer periphery of the rear surface of the object 2 according to the deposition probability, the adhered neutral particles are not removed by an impact of the incident ions. As a result, a deposited material 51 adheres to the outer periphery of the rear surface of the object 2. The above phenomenon is remarkable particularly since a processing gas that is strong in the deposition property is variously used as the application of a new semiconductor material or the fining of the semiconductor device is advanced.

Up to now, there have been proposed several methods of removing the deposited material that has adhered to the outer periphery of the rear surface of the object to be processed in the wafer treatment process as described above. For example, as disclosed in Japanese Patent Application Laid-Open Publication No. 2006-319043, there is a method of removing the deposited material by generating plasma for cleaning along the outer periphery of the rear surface of the object to be processed within a plasma processing chamber in which the etching process is conducted.

Also, as disclosed in US No. 2005/0284568A1, Japanese Patent Application Laid-Open Publication Nos. 2006-287170, 2006-49870, 2006-49869, and 2006-287169, there have been proposed methods of removing the deposited material by activating the deposited material that has adhered to the outer periphery of the rear surface of the object 2 by means of an activated gas. That is, US No. 2005/0284568A1 discloses a configuration that supplies a reactive gas flow to the front surface or the rear surface of a wafer from a nozzle, and also irradiates the front surface or the rear surface with a light to remove the unnecessary film. Japanese Patent Application Laid-Open Publication No. 2006-287170 discloses a configuration that positions the outer periphery of a substrate to a guideway, introduces a reactive gas for removing the undesired material into the guideway, and makes the reactive gas flow along the outer periphery of the substrate.

Japanese Patent Application Laid-Open Publication No. 2006-49870 discloses a configuration that supports a wafer on a stage, supplies a reactive gas such as ozone to the outer periphery of the substrate from a blowing nozzle, and irradiates the substrate with the laser from an irradiating portion that is disposed above the substrate while converging the laser.

In addition, Japanese Patent Application Laid-Open Publication Nos. 2006-49869 and 2006-287169 disclose a configuration that supports a wafer on a stage, locally heats the outer periphery of the rear surface of the wafer by means of a heater, and blows a reactive gas for removing the undesired film from a reactive gas blowout outlet which is disposed in the vicinity of the portion that is locally heated.

### SUMMARY OF THE INVENTION

In the method disclosed in Japanese Patent Application Laid-Open Publication No. 2006-319043, that is, in the case of removing the deposited material that has adhered to the outer periphery of the rear surface of the object to be processed within a plasma processing chamber that conducts etching, the removal rate is not always high because the plasma processing chamber does not originally specialize in removing the deposited material. Also, because a subsequent object to be processed cannot be etched during removal of the deposited material, the throughput is deteriorated.

On the other hand, in the method of supplying the reactive gas to the outer periphery of the object to be processed, and removing the deposited material through a chemical reaction as disclosed in US No. 2005/0284568A1, Japanese Patent Application Laid-Open Publication Nos. 2006-287170, 2006-49870, 2006-49869, and 2006-287169, when the outer periphery of the rear surface of the object to be processed is heated by a laser or a lamp, a microscopic pattern that is formed on the front surface of the object to be processed is also heated at the same time with overheating the outer peripheral surface of the rear surface of the object to be heated. As a result, there is a risk that the microscopic pattern is damaged. Also, in order to prevent a portion where the microscopic pattern is formed from being excessively heated, it is necessary to cool a portion other than the outer periphery of the rear surface of the object to be processed while overheating the outer periphery, and a cooling mechanism that is larger in the cooling performance is located on the stage on which the object to be processed is put. For that reason, there arise such problems that the structure of the stage is complicated, and the costs of the removing device are increased.

In addition, in the conventional system using the chemical reaction, because the deposited material is so removed as to gradually scrape the front surface of the deposited film in a depth direction, there is a concept such as the removal rate in the depth (thickness) direction. For example, in the case where the removal rate is 1000 nm/sec, and the thickness of the deposited film to be removed is 100 nm, a period of time required for removal is 0.1 seconds. When the period of time required for the removing process is 0.05 seconds, the deposited film that is 50 nm in the thickness remains without being removed. Accordingly, a reduction in the processing time per one object to be processed is naturally limited from the viewpoint of the removal rate. For that reason, a period of time required for the entire treatment process including the wafer treatment process and the process for removing the deposited film that has adhered to the wafer which is attributable to the wafer treatment process is elongated, to thereby deteriorate the throughput.

The present invention has been made in view of the above circumstances, and therefore an object of the present invention is to provide a wafer edge cleaner which is capable of removing an undesired material that adheres to an outer periphery of a wafer to be processed at low costs.

Another object of the present invention is to provide a wafer edge cleaner which is capable of removing an undesired material that adheres to an outer periphery of a wafer to be processed with high throughput.

A representative example of the present invention will be described below. That is, the wafer edge cleaner according to the present invention has an unit for irradiating the vicinity of the outer periphery of the rear surface of the wafer with a pulse laser beam to evaporate and remove the undesired material that has adhered to the outer periphery of the rear surface of the wafer.

According to the present invention, it is possible to remove the undesired material that has adhered to the outer periphery of the object to be processed at the low costs. Also, it is possible to remove the undesired material that has adhered to the outer periphery of the object to be processed with the high throughput.

### BRIEF DESCRIPTION OF THE DRAWINGS

These and other features, objects and advantages of the present invention will become more apparent from the following description when taken in conjunction with the accompanying drawings wherein:

FIG. 1 is a schematic diagram showing an entire wafer edge cleaner for explaining a first embodiment of the present invention;

FIG. 2 is a schematic diagram showing a partially enlarged portion of FIG. 1;

FIG. 3 is a schematic diagram showing a partially enlarged portion of FIG. 1;

FIG. 4A is a graph showing an example of the characteristics of a laser;

FIG. 4B is a graph showing an example of the characteristics of a laser;

FIG. 5A is a graph for explaining the characteristic of a laser according to a first embodiment;

FIG. 5B is a graph for explaining the characteristic of a laser according to the first embodiment;

FIG. 6 is a graph showing an example of the characteristics of a laser;

FIG. 7 is a graph for explaining the deposited material on the outer periphery of the rear surface of the object to be processed on the basis of the removal results according to the first embodiment;

FIG. 8 is a graph for explaining a temperature of the object to be processed according to the first embodiment;

FIG. 9A is a graph for explaining a change in the temperature of an object to be processed with time according to the present invention;

FIG. 9B is a graph for explaining a change in the temperature of the object to be processed with time according to the first embodiment;

FIG. 10 is a graph for explaining a deposited material removal result when a laser pulse frequency is low according to the first embodiment;

FIG. 11 is a diagram for explaining an etching device according to a second embodiment of the present invention;

FIG. 12A is a diagram for explaining an irradiated spot of the laser according to the second embodiment;

FIG. 12B is a diagram for explaining the irradiated spot of the laser according to the second embodiment;

FIG. 13A is a diagram for explaining an irradiated spot of a laser according to a third embodiment;

FIG. 13B is a diagram for explaining the irradiated spot of the laser according to the third embodiment;

FIG. 13C is a diagram for explaining the irradiated spot of the laser according to the third embodiment;

FIG. 14 is a diagram for explaining an optical system of the laser according to the third embodiment;

FIG. 15A is a diagram for explaining a mechanism in which a deposited material adheres to the outer periphery of a rear surface of an object to be processed; and

FIG. 15B is a diagram for explaining a mechanism in which a deposited material adheres to the outer periphery of a rear surface of an object to be processed.

### DETAILED DESCRIPTION OF THE PREFERRED EMBODIMENTS

According to a representative embodiment of the present invention, there is provided a wafer edge cleaner including a laser source of the pulse oscillation type, a stage for mounting a wafer, and a rotation mechanism for rotating the stage in a circumferential direction. In the wafer edge cleaner, an outer periphery of a rear surface of an object to be processed is irradiated with a pulse laser beam that is 30 kW/mm² or higher in the peak power density of the laser beam, thereby evaporating a deposited material that adheres to the outer periphery of the rear surface of the object to be processed by the aid of instantaneous heating to remove the deposited material.

Even if the outer periphery of the rear surface of the object to be processed is locally heated up to a temperature of the degree that evaporates the deposited film to evaporate the deposited film for removal of the deposited film, it is possible to sufficiently suppress a rise in a portion other than the outer periphery of the rear surface of the object to be processed. For that reason, a supply mechanism of a reactive gas which has been used to remove the deposited film by the aid of a chemical reaction is not required, thereby reducing the costs of the removing device.

Also, the system of evaporating the deposited material by heating due to the pulse laser permits an upper layer to a lower layer of the deposited film to be heated together and evaporated instantaneously. For that reason, there is advantageous in that a period of time required for processing is remarkably reduced as compared with the system using a chemical reaction to improve the throughput.

Hereinafter, a description will be given of embodiments of the present invention with reference to the accompanying drawings.

### First Embodiment

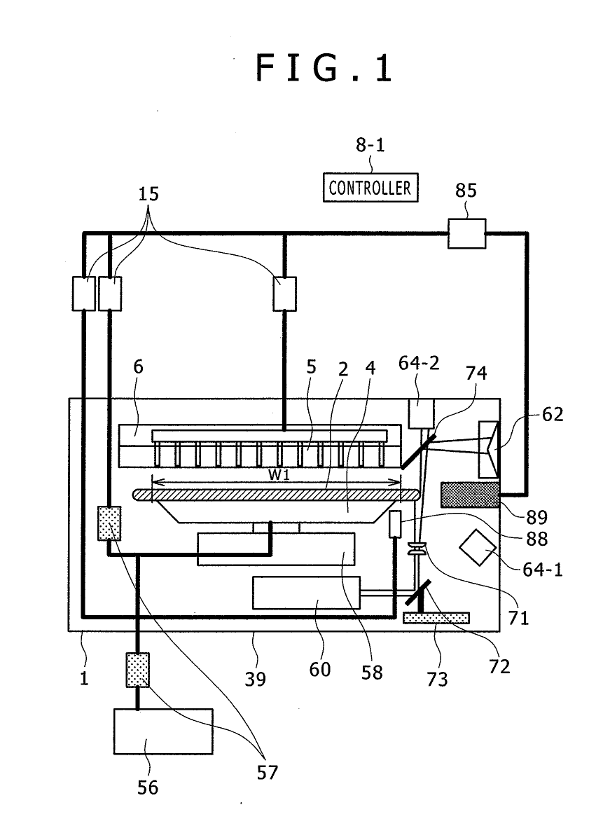

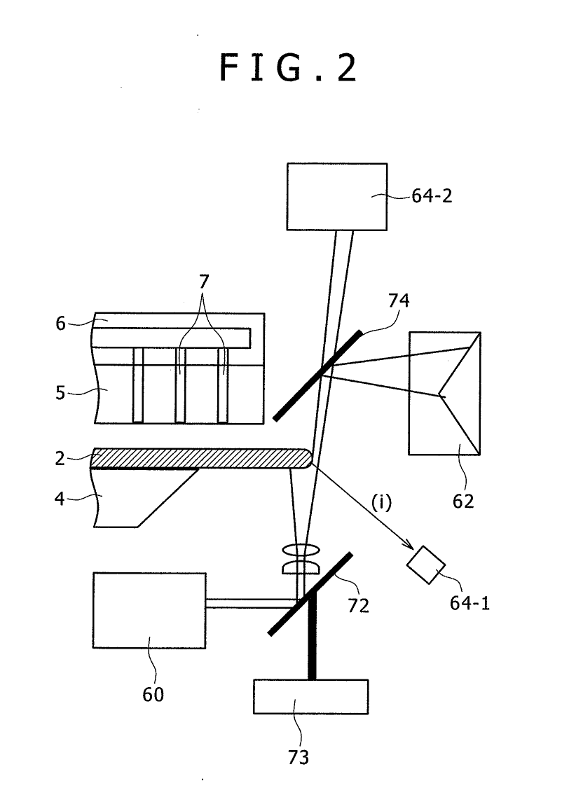

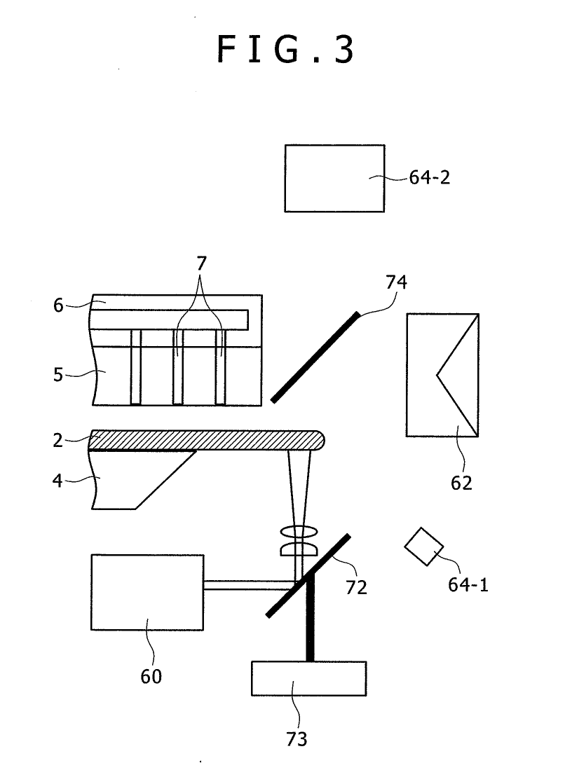

First, a first embodiment of the present invention will be described with reference to the accompanying drawings. FIG. 1 shows the outline of an entire wafer edge cleaner. FIGS. 2 and 3 are diagrams for explaining the operation of the first embodiment, and show partially enlarged portions of FIG. 1, respectively. The wafer edge cleaner has a removal processing chamber 1 for a substantially ambient atmosphere, and a wafer (a sample) 2 that is an object to be processed is located on a stage 4 which is disposed within the removal processing chamber 1. The stage 4 is equipped with a rotary mechanism 58 for allowing the object 2 to rotate in the circumferential direction and a control unit for the rotary mechanism 58. In order to prevent the object 2 from being displaced from the stage 4 during the rotation of the object 2, the wafer edge cleaner is configured such that the object 2 can be chucked to the stage 4 under vacuum. In other words, because of the vacuum chuck, a gas flow passage (not shown) is disposed in a surface of the stage 4 on which the object 2 is put, and when the object 2 is fixed to the stage 4, the interior of the flow passage is depressurized to exhaust a gas therefrom by means of a dry pump 56.

Over the stage 4, substantially disc-shaped shower plate 5 and a dispersion plate 6 for supplying dry air to the sample 2 are installed. Multiple gas holes 7 are provided in the shower plate 5. The dispersion plate 6 is connected through a pressure control valve 15 and a passage to a dry air source 85. The dry air source 85 is also connected to an introduction nozzle 88 under the periphery of the stage 4 and to the dry pump 56 through the passage, the pressure control valves 15 and a switching valve 57.

In this embodiment, a dry air source 85 for supplying the dry air is connected to a gas flow passage in the stage 4, and when the object to be processed is detached from the stage 4, a treatment dry air is supplied to the gas flow passage. In this example, the dry air is an air having a low dew point that is 0° C. or lower in a dew point temperature. A diameter W1 of the stage 4 on which the object to be processed is put is set to be smaller than a diameter W2 of a surface of an electrode, on which the object to be processed is put, for mounting the object to be processed in a plasma processing device used in a step of adhering a deposited material to the outer periphery of the rear surface of the object to be processed. With the above configuration, a portion of the outer periphery of the rear surface of the object to be processed to which the deposited material adheres is sufficiently protruded from the stage. Then, the deposited material that has adhered to the outer periphery of the rear surface of the object to be processed is irradiated with a pulsed laser beam to remove the deposited material while the object to be processed is rotated in the circumferential direction.

The laser beam is emitted from a laser source 60, and then reflected by a mirror 72. The laser beam that has been reflected by the mirror is adjusted to a given beam diameter by the lens 71, and the outer periphery of the rear surface of the object to be processed is irradiated with the laser beam. The irradiated position on the object to be processed is adjusted according to an angle of the mirror and a horizontal position. The mirror is fitted to a mirror position controller 73. The wafer edge cleaner is equipped with a mirror control mechanism that is capable of controlling the position and angle of the mirror. With the above configuration, for example, as shown in FIG. 2, the outermost periphery of the object to be processed can be irradiated with the laser beam, or as shown in FIG. 3, a portion on the slight inside of the outermost periphery can be irradiated with the laser beam. Also, when the center of the object to be processed and the center of the rotation axis of the stage are slightly deviated from each other, the rotation of the object to be processed and the mirror position can be interlocked with each other according to the quantity of deviation.

Also, a photodetector 64-1 such as a photodiode is located within the removal processing chamber. The photodetector 64-1 is so designed as to detect the laser beam that has been reflected by an edge of the object to be processed while moving the mirror, thereby enabling the outer peripheral position of the object to be processed to be detected. For example, as shown in FIG. 2, when the outermost periphery of the object to be processed is irradiated with the laser beam, the laser beam is reflected by a corner (curved portion) of the object to be processed, and a part of laser beam is input to the photodetector 64 (a line i in FIG. 2). On the contrary, when the corner of the outermost periphery of the object to be processed is not irradiated with the laser beam as shown in FIG. 3, the scattered laser beam is hardly input to the photodetector for detecting the scattered beam from the edge of the object to be processed. Accordingly, the scattered laser beam is monitored by the photodetector while the mirror is slightly moved, thereby making it possible to determine whether the outermost periphery is irradiated with the laser beam, or not.

When the laser beam that has been deviated from the object to be processed is rebounded by a top board or the inside of the removal processing chamber, and a microscopic pattern on the surface of the object to be processed is irradiated with the laser beam, there is a risk that the irradiated portion is locally heated, and the microscopic structure is destroyed. Under the circumstances, in order to allow the laser beam that has been deviated from the object to be processed to be terminated by a beam damper 62, a half mirror 74 is located above the object to be processed so that the laser beam is reflected in a given direction.

Also, a photodetector 64-2 is located in a beam transmission direction of the half mirror, and so designed as to detect the edge of the object to be processed by detection of the laser beam as with the photodetector 64-1. In other words, as shown in FIG. 2, when the outermost periphery of the object to be processed is irradiated with the laser, the laser beam is partially deviated from the object to be processed, and reaches the half mirror 74, and a part of laser beam is transmitted through the half mirror and input to the photodetector.

On the contrary, as shown in FIG. 3, when the slight inside of the outer periphery of the object to be processed is irradiated with the laser beam, because the laser beam does not reach the half mirror, no laser beam is input to the photodetector 64-2 that is disposed in the transmission direction of the half mirror. For that reason, when the position of the mirror is adjusted while the input of the laser beam is monitored by the photodetector 64-2, it is possible to detect the outer periphery of the object to be processed. It is preferable to use the half mirror having the reflectivity/transmissivity that reflects most of the laser beam, for example, 98% and terminates the reflected laser beam at the beam damper, and allows the transmission of the slight laser beam, for example, about 2%, so as to input the laser beam to the photodetector 64-2.

In order to prevent the deposited material that has been evaporated by irradiation of the laser beam from again adhering to the object to be processed, a shower plate 5 is so located as to face the stage 4, and a dry air is supplied toward the object to be processed from the shower plate. The flow of air enables the evaporated deposited material to be prevented from flying toward the object to be processed. Also, a gas introduction nozzle 88 is so located as to supply the dry air between the laser irradiated position of the evaporated deposited material and the stage. When the object to be processed is fixed by the vacuum chuck, there is a risk that the air is sucked from a slight gap between the stage and the object to be processed, and when the air containing the evaporated deposited material is sucked, the rear surface of the object to be processed or the stage is contaminated. In order to prevent the contamination of those members, the dry air is supplied from the gas introduction nozzle 88, the gas that is sucked by the vacuum chuck is treated as the dry air, and the deposited material that has been evaporated by irradiation of the laser beam is transported in the outer periphery of the object to be processed. The air that is supplied from the shower plate or the air that is supplied to the vicinity of the outer periphery of the rear surface of the object to be processed can be made of a gas such as hydrogen, nitrogen, or CF gas, other than air.

Also, because the inner wall of the removal processing chamber of a wafer edge cleaner is contaminated by again adhering of the evaporated deposited material, it is preferable that the inner wall is removed as an inner wall member, and a swap part is used. Also, because the deposited material is evaporated within the removal processing chamber by irradiation of the laser beam, the air containing the deposited material is exhausted from an exhaust nozzle 89, returns to the dry air source 85, and removes the evaporated deposited material. A pressure within the removal processing chamber is negative with respect to the atmosphere. It is desirable that the exhaust nozzle is located at a position close to the laser irradiated position of the object to be processed as much as possible. The wafer edge cleaner has a controller 8-1 that controls the entire operation.

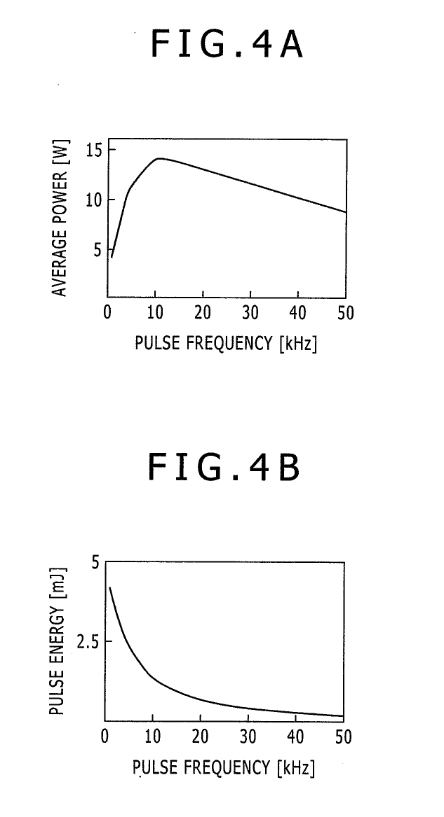

Subsequently, a description will be given of a specification necessary for the laser source with reference to FIGS. 4A, 4B, 5A, 5B, and 6. As indexes representative of the characteristics of the laser source, there are an average power, a pulse energy, a pulse width, a peak power, and pulse frequency other than the wavelength. The characteristics of those parameters will be described with an example of the laser source (YAG laser that is 532 nm in the wavelength) using a basic experiment.

First, FIG. 4A shows an example of the average power. The average power is an accumulated energy of the laser beam that oscillates in one second, and depends on the pulse frequency. The unit of the average power is [W] (watt). In an example shown in FIG. 4A, the average power is 14 W at maximum when the pulse frequency is 10 kHz. The pulse energy is an energy per one laser pulse, and its unit is [J] (joule). The pulse energy also depends on the pulse frequency, and its example is shown in FIG. 4B. The pulse energy has a tendency to increase with decrease of pulse frequency. The average power, the pulse energy, and the pulse frequency have the following relational expression.

Average Power=Pulse Energy×Pulse Frequency

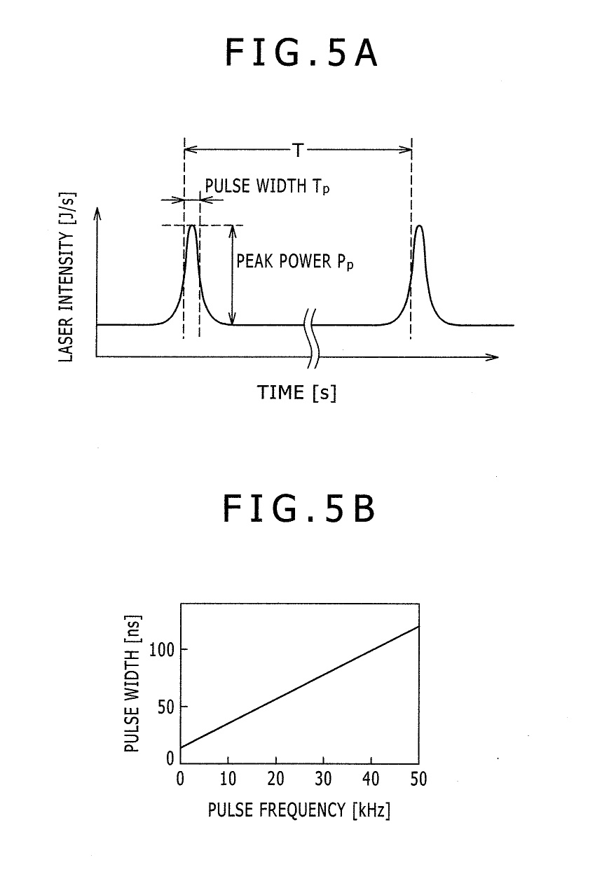

Subsequently, the pulse width represents a period of time during which one laser pulse is oscillated as shown as Tp in FIG. 5A, and the unit is [s] (seconds). Reference T denotes a pulse interval (=inverse proportion to pulse frequency). The pulse width also depends on the pulse frequency, and its example is shown in FIG. 5B. The pulse width is smaller as the pulse frequency is lower. For example, the pulse width is about 40 ns when the pulse frequency is 10 kHz, but becomes smaller, that is, about 15 ns when the pulse frequency is 1 kH.

Subsequently, the peak power means the instantaneous maximum power when the laser oscillates as shown in FIG. 5A, and the unit is [J/s]. The peak power can be approximately represented by the following expression by using the pulse energy and the pulse width.

Peak Power≈(almost equal) Pulse Energy/Pulse Width

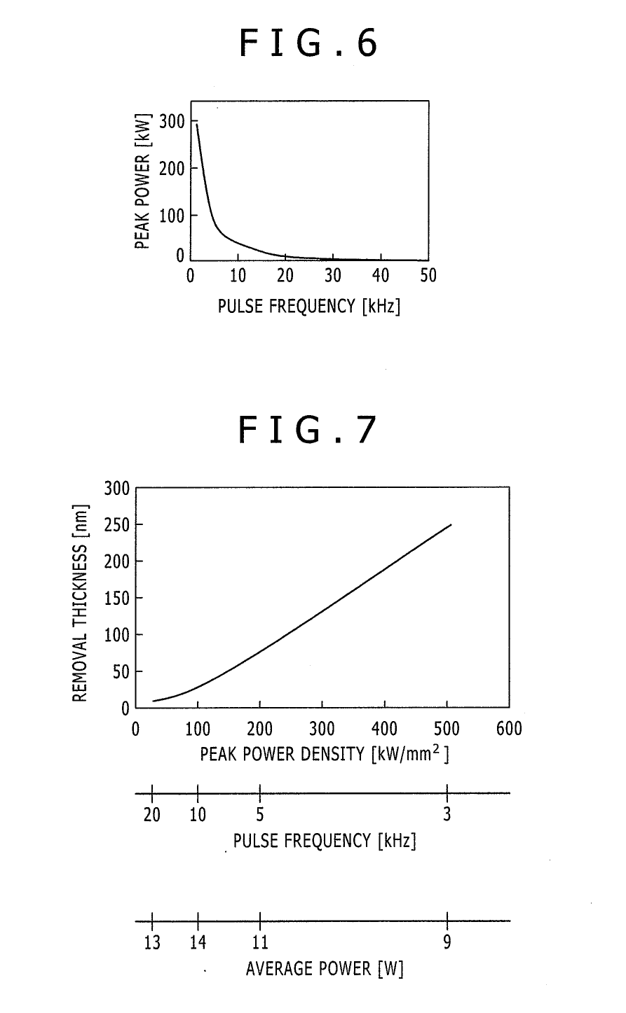

The peak power depends on the pulse frequency as shown in FIG. 6. For example, when the pulse frequency is 10 kHz, the peak power is about 40 kW whereas the pulse frequency is 1 kHz, the peak power increases up to about 300 kW.

An attempt has been made to remove the deposited film of the outer periphery of the rear surface of the object to be processed by the aid of the laser having the characteristics shown in FIGS. 4A to 6. The results will be described below. FIG. 7 shows the removal performance when (the axis of abscissa is) the horizontal axis denotes the power density, and (the axis of ordinate is) vertical axis denotes the removal thickness of the deposited film. The beam section of the laser is substantially circular, and the diameter of the beam at the irradiated position of the object to be processed is about 0.7 mm. The object to be processed is an Si wafer that is 300 mm in the diameter, and the rotating speed is one rotation (about 3 rpm) per about 20 seconds. In this example, the peak power density is represented by the following expression by using the peak power and the beam sectional area.

Peak Power Density=Peak Power/Beam Cross Section

As is understood from FIG. 7, the results are that the removal quantity is larger as the peak power density is larger, for example, when the peak power density is 500 kW/mm², the deposited film having the thickness of about 250 nm can be removed. On the contrary, when the peak power density is 30 kW/mm², the removal quantity is about 10 nm. Also, FIG. 7 roughly shows the laser pulse frequency and the average power in addition to the peak power density on the axis of abscissa. The removal quantity is large when the peak power density is larger even if the average power is low. Thus, it is found that the peak power density determines the removal performance. Also, because all of data in FIG. 7 is identical in the rotating speed of the wafer, the number of laser irradiations per one point is increase more as the pulse frequency is higher. The removal quantity is larger when the pulse frequency is smaller, that is, the peak power density is larger although the number of irradiations per one point is smaller. Also, it is found that the peak power density determines the removal performance. FIG. 7 does not show the removal performance when the peak power density is equal to or lower than 30 kW/mm². This is because, according to the experiment, when the peak power density is smaller than 30 kW/mm², the removal performance cannot be quantified due to a variation in the initial film thickness of the deposited film.

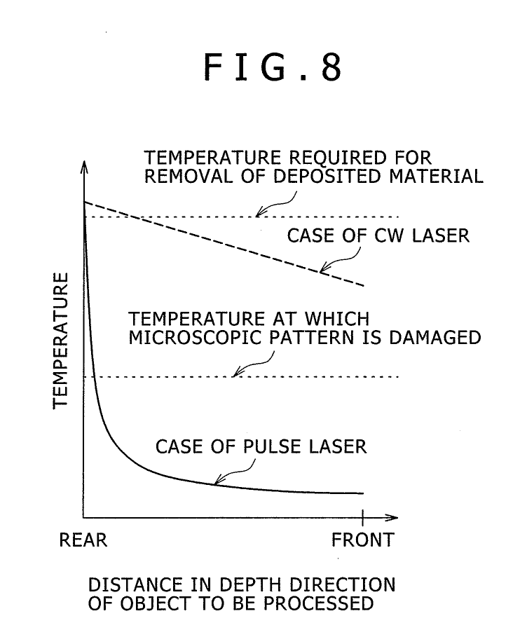

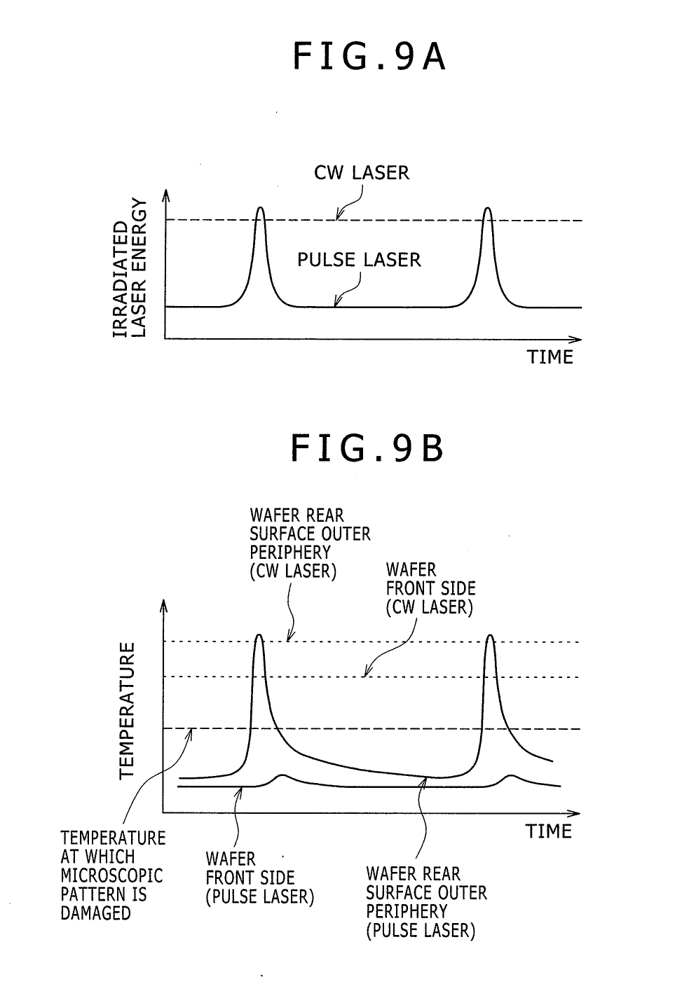

In the CW laser of the continuous wave oscillation type, it is difficult to remove the deposited film, and it is necessary to use the pulse laser that is larger in the peak power density. This will be described with reference to FIGS. 8 to 9B.

First, FIG. 8 shows the temperature distribution in the depth direction of the object to be processed in the pulse oscillation laser and the CW laser. In the pulse oscillation laser, the temperature distribution is measured roughly at the moment that the peak power turns on. FIGS. 9A and 9B show the comparisons of a change in the temperature of the front surface and the rear surface of the object to be processed with time between the pulse oscillation type laser and the CW type laser. As shown in FIG. 8, in the case of the pulse oscillation type laser, even if the deposited film that has adhered to the rear side of the object to be processed is heated to a temperature required for evaporation of the deposited film, the temperature of the front side of the object to be processed hardly rises. On the contrary, when the deposited film is heated to a temperature required for evaporation of the deposited film by the aid of the CW laser, the temperature of the surface of the object to be processed exceeds a temperature at which the microscopic pattern is damaged.

Subsequently, a change in the temperature of the object to be processed with time will be described with reference to FIGS. 9A and 9B.

As indicated by a solid line in FIG. 9A, in the pulse oscillation laser, a period of time for which one laser pulse is irradiated is a moment of, for example, 20 ns. There is an interval of 1 ms, that is, 1000000 ns until a subsequent laser pulse is irradiated. For that reason, as indicated by a solid line in FIG. 9B, even if the outer periphery of the rear surface of the object to be processed is momentarily heated at a high temperature, the heat is diffused in a much longer period of time than the period of time during which one laser pulse is irradiated. For that reason, the temperature of the surface side of the object to be processed hardly rises. On the contrary, in the CW laser, because the outer periphery of the rear surface of the object to be processed is always heated as indicated by a broken line in FIG. 9A, a temperature of the front surface side of the object to be processed easily exceeds the temperature at which the microscopic pattern is damaged, as indicated in FIG. 9B. For the above reason, it is found that it is necessary to use the laser of the pulse oscillation type that is large in the peak energy.

As described above, according to the present invention, the pulsed laser beam is irradiated without using the reactive gas, to thereby locally and instantaneously supply a high energy to the deposited material, and gasify and evaporate only the deposited material in the irradiated area. Since the deposited material is locally and instantaneously irradiated with the pulsed laser beam, the supply heat quantity is limited, and the energy is not transmitted to the surface of the object to be processed. For that reason, it is desirable that the laser beam that is supplied from the laser source is long in the pulse interval. In other words, when it is assumed that the percentage of one cycle (pulse interval) T whom the pulse width Tp of the pulse laser accounts for is a duty ratio, it is desirable that the duty ratio is equal to or lower than 0.01. For example, when the pulse interval is 1 msec, the pulse width is 30 nsec. In this case, the duty ratio is 0.00003. A desirable range of the duty ratio depends on the conditions such as the oscillation frequency or the wafer rotating speed of the pulse oscillation laser. However, it is desirable that the duty ratio is in a range of 10⁻⁸ to 10⁻².

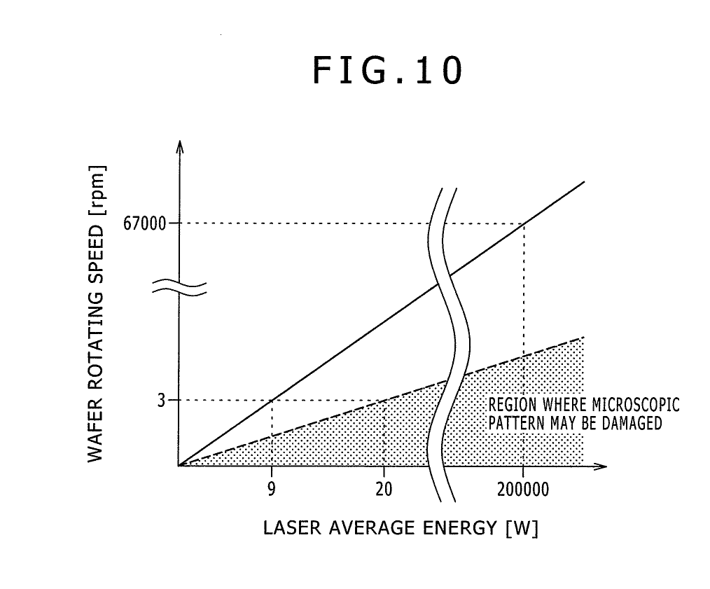

Subsequently, a description will be given in brief of the average energy of the laser and the rotating speed of the wafer, which are so set as to prevent the wafer from being damaged with reference to FIG. 10. In FIG. 10, the axis of abscissa represents the average energy of the laser, and the axis of ordinate is a wafer rotating speed. In FIG. 10, a solid line represents a relationship between the laser average power and the wafer rotating speed when a reference heat quantity that is supplied to a wafer when the wafer rotates 360 degrees while the wafer is irradiated with the laser beam having an irradiated spot which is about 0.7 mm in diameter and 500 kW/mm² in the peak power density is identical with the heat quantity that is supplied to the wafer during one revolution of the wafer by using a laser source having the characteristics shown in FIGS. 4A to 6.

As is apparent from FIG. 10, when the laser that is high in the average power is used, the wafer must rotate at a higher speed. For example, in the case of using the laser source that is about 200 kW in the average output, the rotating speed of the wafer is 67000 rpm. In other words, when the wafer rotates slowly by using the laser that is high in the average power, the microscopic pattern on the wafer surface is damaged by overheating.

Now, let us remarkably simply consider the required wafer rotating speed in the case of using the CW laser. When the CW laser source that is about 200 kW in the average output is used, and the beam irradiated diameter is set to 0.7 mm, the peak power density is assumed as 500 kW/mm². Then, as shown in FIG. 10, when the average energy of the laser is 200 kW, the heat quantity that is supplied to the wafer by rotating the wafer at the rotating speed of about 67000 rpm by 360 degrees is identical with that when the wafer rotates at the rotating speed of about 3 rpm by 360 degrees by the aid of the pulse laser that is 500 kW/mm² in the peak power density. The microscopic pattern on the wafer front surface is not damaged.

However, there is no benefit obtained by using a CW laser having a great output that is, for example, 200 kW in the average output, which is about 20000 times as large as other laser, in order to remove the deposited film having the same thickness, although the deposited film that is 250 nm in the thickness can be removed by the laser that is 9 W in the average energy and 200 kW in the peak power (peak power density of 500 kW/mm²). Also, even if the laser source of the above unreal great output is used, it is factually impossible to rotate the wafer at a very high speed such as 67000 rpm. The benefit obtained by using not the CW laser but the pulse laser is understood from the above fact.

In order to prevent the microscopic pattern on the wafer surface from being damaged, when the rotating speed of the wafer is about 3 rpm, the average irradiation power of the laser must be suppressed to about 20 W (broken line in FIG. 10). In this case, a relationship between the laser average power and the wafer rotating speed which are required in order to prevent the microscopic pattern from being damaged is expressed as follows.

Wafer rotating speed [rpm]>0.15=Irradiated average energy of the laser [W]

0.15 of the coefficient is a value specific to the removing device which is obtained from the device used in the experiment, and changes depending on the cooling performance of the wafer such as the stage. When the cooling performance of the wafer such as the stage is twice as large as the original, the coefficient is simply half.

As described above, according to the wafer edge cleaner of this embodiment, the outer periphery of the rear surface of the wafer is irradiated with the laser beam that is 30 kW/mm² or larger in the peak power density of the laser beam, to thereby gasify the deposited material that has adhered to the outer periphery of the rear surface of the wafer by instantaneously heating so as to remove the deposited material. Similarly, when the outer periphery of the rear surface of the wafer is locally heated up to a temperature of the degree that the deposited film is evaporated by irradiation of the pulse laser to gasify the deposited material for removal, it is possible to sufficiently suppress a rise in the temperature of a portion other than the outer periphery of the rear surface of the wafer. For that reason, the supply mechanism of the reactive gas that has been used to remove the deposited film by a chemical reaction is not required, and the costs of the removing device are reduced. Also, the front layer to the lower layer are heated in a lump, and instantaneously evaporated. For that reason, there is advantageous in that a period of time required for processing is significantly reduced as compared with the system using the chemical reaction, thereby enabling the throughput to be improved.

### Second Embodiment

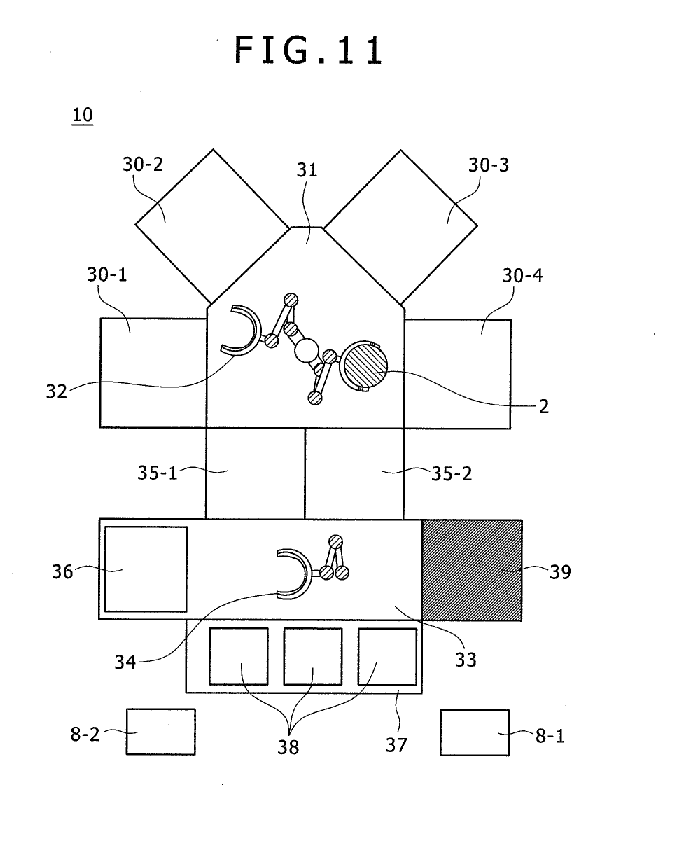

Subsequently, a description will be given of a second embodiment that combines the etching device with the wafer edge cleaner of the present invention. As shown in FIG. 11, the plasma processing device according to this embodiment includes a plasma processing unit 10, a wafer edge cleaner 39 for removing the deposited material on the outer periphery of the rear surface of an object to be processed which has been processed by the plasma processing unit, and a system controller 8-2. That is, the wafer edge cleaner (removal processing chamber) 39 shown in FIG. 1 is combined with an atmospheric side transport chamber 33 of the plasma processing device including the atmospheric side transport chamber 33, lock chambers 35, a vacuum side transport chamber 31, and four etching chambers 30. In this embodiment, the plasma processing unit 10 has the four plasma processing chambers 30 (30-1 to 30-4) and the two lock chambers 35 (35-1, 35-2) connected to a vacuum transport system (the vacuum transport chamber 31 and a vacuum transport robot 32). The respective plasma processing has a vacuum treatment chamber, a lower electrode (specimen stand) that is located within the vacuum treatment chamber for putting the object to be processed thereon, and a supply source that supplies a high frequency electromagnetic field for generating the plasma within the vacuum treatment chambers, or a supply source that supplies a processing gas. Also, each of the vacuum treatment chambers is connected with a turbo molecule pump for reducing a pressure within the chamber (not shown). The atmospheric side transport chamber 33 is connected to a vacuum transport system through a lock chamber 35 for switching over room air and vacuum atmosphere. An atmospheric transport robot 34 for transporting the object to be processed and an aligner 36 for detecting a notch position of the object to be processed and the center of the object to be processed while rotating the object to be processed 2 are located in the atmospheric side transport chamber 33. Also, a wafer station 37 is also located in the atmospheric side transport chamber 33 in order to dispose a front opening unified pod (FOUP) 38 for housing the object to be processed.

The atmospheric side transport chamber 33 is connected with a wafer edge cleaner 39 that cleans the outer periphery of the object to be processed. The system controller 8-2 entirely controls the transport of the wafer, the etching process, and the removing process in the plasma processing unit and the wafer edge cleaner.

The wafer that is taken out of the FOUP 38 by the means of the atmospheric transport robot 34 one by one is transported into the vacuum treatment chamber through the lock chamber 35 by the aid of the vacuum transport system, and then etched. The processed wafer is transported to the lock chamber 35 by the aid of the vacuum transport system, transported to the aligner 36 from the lock chamber 35 by means of the atmospheric transport robot 34, and transported to the wafer edge cleaner 39 after being positioned. In this situation, the deposited material that has adhered to the outer periphery of the rear surface of the object to be processed with the processing in the plasma processing unit is removed. The wafer that has been completely subjected to the removing process is recovered to the FOUP 38 by means of the atmospheric transport robot 34.

In this embodiment, a description will be given of a relationship between the pulse frequency of the laser and the rotating speed of the object to be processed, which is required to evenly remove the undesired deposited film that has adhered to the outer periphery of the rear surface of the wafer with the etching process of the wafer in the case of using the wafer edge cleaner in combination with the etching device. This relationship determines a period of time required to remove the deposited material in one object to be processed.

When it is assumed that a period of time required for etching the object to be processed is 2 minutes per one object to be processed in the etching chamber, it is possible that the plasma etching device having four processing chambers etches two objects to be processed per minute. In order to process the object to be processed which has been etched by means of the wafer edge cleaner on time, there is required a performance of removing the deposited film on the outer periphery of the rear surface of the object to be processed at a rate of one object to be processed per 30 seconds.

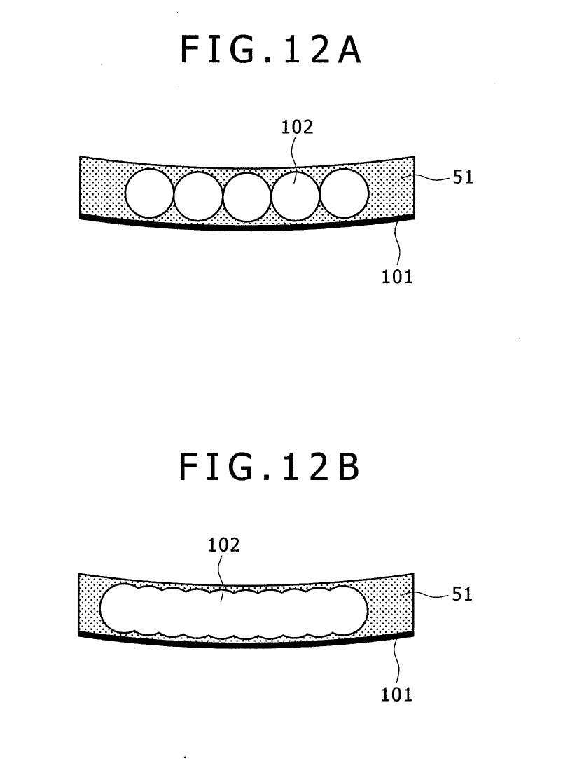

In this case, the required rotating speed of the wafer stage in the wafer edge cleaner is higher than 2 rpm (30 seconds/times). Now, as an example of the undesired combination of the rotating speed of the object to be processed with the laser pulse frequency, FIG. 12A shows the deposited material removal results when the rotating speed of the object to be processed is about 6 rpm (about 10 seconds/times), and the laser pulse frequency is about 100 Hz. Reference numeral 51 denotes a deposited material, and 101 is a wafer edge. Circular patterns 102 are apparent in FIG. 12A, which are removal marks in each of laser shots. The reason that the removal marks 102 appear is because the rotating speed of the wafer is too high while the laser pulse frequency is small. The average number of laser irradiations at one point is roughly represented by the following expression using the rotating speed [rps] of the wafer, the laser pulse frequency [Hz], the laser irradiation diameter (width) [m], and the wafer diameter (diameter) [m].

The number of average irradiations=laser irradiation diameter×laser pulse frequency/(wafer diameter×π×wafer rotating speed)

When the number of average irradiations is one, the irradiated spots (removal marks 102) are produced as shown in FIG. 12A, and when the number of average irradiations is two, the irradiated spots are produced as shown in FIG. 12B. In order to completely remove the deposited object while the object to be processed rotates 360 degrees, the number of irradiations must be increased at least more than once. In this case, the following expression must be satisfied.

Wafer diameter×π×Wafer rotating speed<Laser irradiation diameter×Laser pulse frequency

For example, when the laser irradiation diameter is 1 mm, the wafer rotating speed is 0.05 rps (20 seconds/times), and the wafer diameter is 300 mm, in order to set the average number of irradiations to more than one, the laser pulse frequency must be set to 120 Hz or higher.

According to this embodiment, there can be provided the wafer edge cleaner that is capable of removing the undesired material that has adhered to the outer periphery of the object to be processed with a simple structure, in other words, at the low costs. Also, there is advantageous in that a period of time required for processing is significantly reduced as compared with the system using the chemical reaction, thereby enabling the throughput to be improved. Further, the processed wafer is transported directly to the wafer edge cleaner from the etching chamber through the lock chamber by means of an atmospheric transport device, and the wafer that has been completely subjected to the removing process is recovered to the original FOUP 38. As a result, the wafer having the undesired material adhered to the outer periphery of the rear surface of the object to be processed is housed in the FOUP. As a result, there is advantageous in that there is no risk that the deposited object is peeled off within the FOUP, and contaminates the interior of the FOUP.

### Third Embodiment

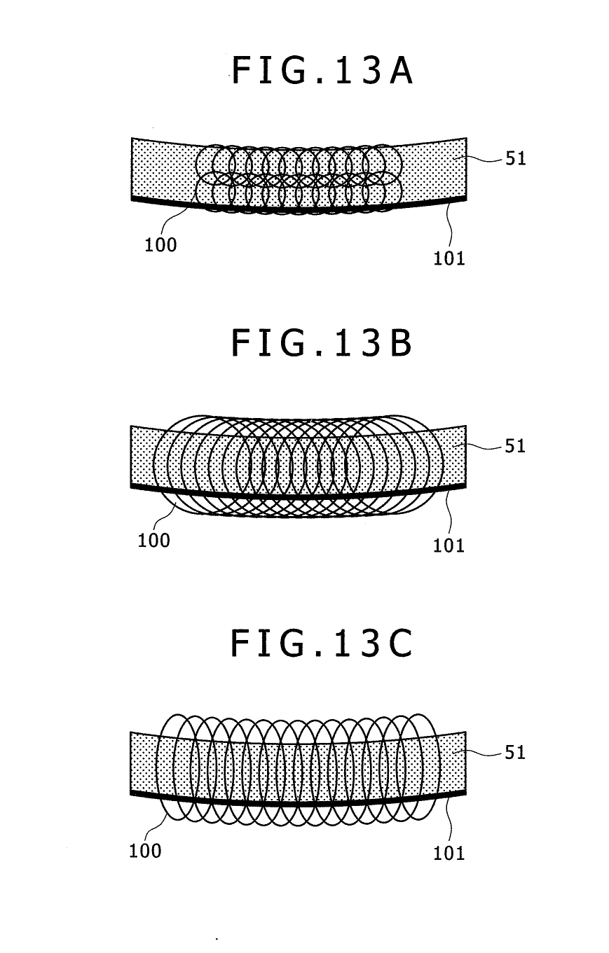

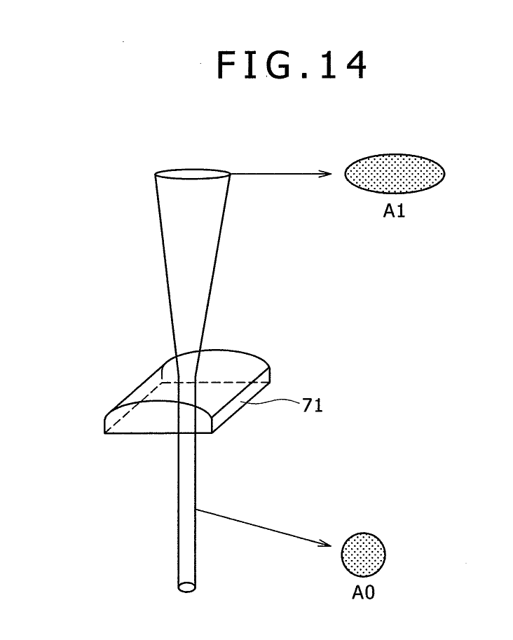

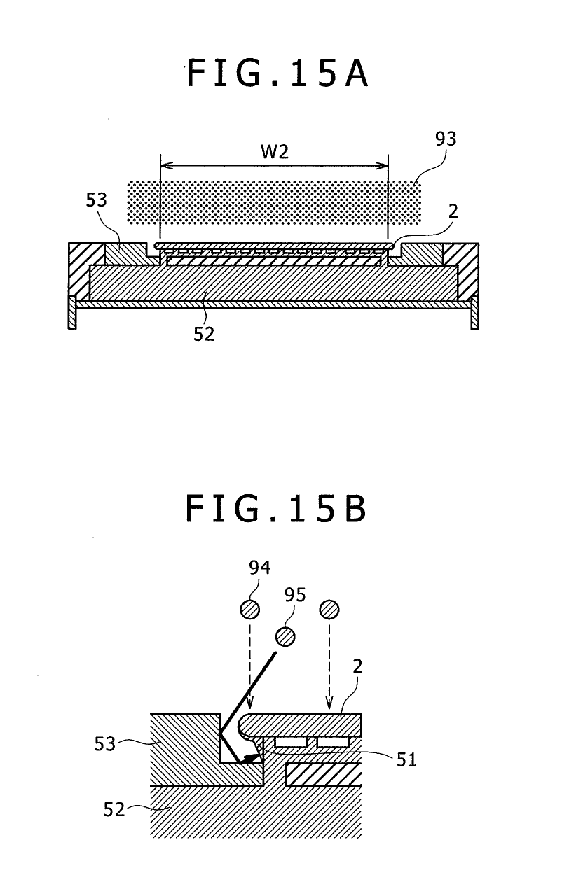

A third embodiment according to the present invention will be described with reference to FIGS. 13A to 13C and 14.

In the above embodiments, the cross-sectional configuration of the irradiated laser beam is circular. Subsequently, the cross-sectional configuration and size of the laser beam will be described. As has been described above, the peak power density is important in the removal of the deposited film. In order to increase the peak power density, there is a method in which a laser source that is high in the peak power is used, or the irradiated diameter of the laser beam is reduced. In the case where the laser sectional configuration is circular, and the beam diameter at the irradiated position is smaller than the adhered width of the deposited film, there is, for example, a method in which the deposited film of the edge portion of the object to be processed is first removed, and the position of the mirror 72 is then displaced to remove the deposited film of the inner portion of the object to be processed, as shown in FIG. 13A. Reference numeral 100 denotes a laser irradiated spot. In the example of FIG. 13A, it is necessary to rotate wafer by at least two revolutions. When the deposited film is going to be perfectly removed by one revolution of the object to be processed, the laser irradiated diameter must be enlarged. The cross section that is enlarged while maintaining the circular configuration is shown in FIG. 13B. When the irradiated diameter of the laser is twice as large as the original, the irradiated cross section of the laser becomes four times as large as the original. As a result, in the case of using the laser source having the same specification, the peak power density is reduced to ¼ as compared with the case shown in FIG. 13A.

On the contrary, for example, the irradiated cross-section that is enlarged by means of a cylindrical lens 71 and irradiated as shown in FIG. 14 is shown in FIG. 13C. When it is assumed that the shorter diameter of the ellipse is kept to that as shown in FIG. 13A, and the longer diameter is twice as large as that in FIG. 13A, the peak energy density is suppressed to a deterioration of ½. Accordingly, in the case of using the laser source having the same performance, the peak power density in FIG. 13C is twice as large as that in FIG. 13B. In other words, the case of FIG. 13C is advantageous in that the peak energy necessary for the laser source becomes half, and the device costs of the laser source is inexpensive as compared with FIG. 13B.

As has been described above, according to this embodiment, there can be provided the wafer edge cleaner that is capable of removing the undesired material that has adhered to the outer periphery of the object to be processed with a simple structure, in other words, at the low costs. Also, there is advantageous in that a period of time required for processing is significantly reduced as compared with the system using the chemical reaction, thereby enabling the throughput to be improved. Further, because of a system that instantaneously gasifies and removes the deposited material, it is unnecessary to install a grand cooling function of the object to be processed on the stage, and the device costs can be reduced.

The present invention can be widely applied to a case that requires undesired material that has adhered to the outer periphery of the rear surface of the wafer to be removed in the original processing in the respective devices in a thin film forming apparatus for the wafer such as a CVD device, a sputter deposition device, or a vapor deposition device, or a microscopic processing device for the wafer such as the etching device.

What is claimed is:

1. A wafer edge cleaner comprising a unit for irradiating a vicinity of a rear surface outer periphery of a wafer with a pulsed laser beam to gasify and remove an undesired material that adheres to the rear surface outer periphery of the wafer.

2. The wafer edge cleaner according to claim 1, comprising:
a removing chamber that substantially removes an ambient atmosphere;
a stage that is located within the removing chamber for putting a wafer thereon;
a rotating mechanism for rotating the stage in a circumferential direction; and
a pulse oscillation laser that generates a pulsed laser beam that is irradiated onto the wafer.

3. The wafer edge cleaner according to claim 2,
wherein the rotating speed of the stage which is conducted by the rotating mechanism is controlled to meet the following relational expression of a wafer diameter, a laser beam diameter that is generated by the pulse oscillation laser, and a laser pulse frequency:
Wafer diameter×π×Rotating speed<Laser beam diameter×Laser pulse frequency.

4. A wafer edge cleaner, comprising:
a pulse oscillation laser source;
a stage for putting a wafer thereon;
a rotating mechanism for rotating the stage in a circumferential direction; and
a controller,
wherein a rear surface outer periphery of the wafer is irradiated with a pulsed laser beam that is 30 kW/mm² or higher in the peak power density to remove an undesired object that adheres to the rear surface outer periphery of the wafer.

5. The wafer edge cleaner according to claim 4,
wherein when it is assumed that the percentage of one cycle whom the pulse width of the pulsed laser beam accounts for is a duty ratio, the duty ratio is controlled in a range of 10⁻⁸ to 10⁻².

6. The wafer edge cleaner according to claim 5,
wherein an average output of the laser beam is 100 W or lower, and the frequency of the laser beam is in a range of 100 Hz to 100 KHz.

7. The wafer edge cleaner according to claim 4,
wherein the wafer edge cleaner includes at least one of irradiation angle adjusting means for adjusting the irradiation angle of the laser beam with respect to the wafer and irradiation position adjusting means for adjusting the irradiation position of the laser beam.

8. A wafer edge cleaner, comprising:
a removing chamber that substantially removes an ambient atmosphere;
a pulse oscillation laser source for irradiating a rear surface outer periphery of a wafer with a laser beam;
a stage for putting the wafer thereon;
a rotating mechanism for rotating the stage in a circumferential direction; and
a controller,
wherein the configuration of an irradiation spot of the laser beam in the radial direction of the wafer is controlled longer than that in the circumferential configuration for irradiation to widen a removal width in the radial direction of the wafer.

9. The wafer edge cleaner according to claim 8, wherein the laser source has a cylindrical lens.

10. The wafer edge cleaner according to claim 8,
wherein the rear surface outer periphery of the wafer is irradiated with a laser beam that is elliptical in cross section and 30 kW/mm² or higher in peak power density from the laser source.
